(19) United States
(12) Patent Application Publication
(10) Pub. No.: US 2026/0331061 A1
(43) Pub. Date: Oct. 22, 2026

(54) Stage Circuit, Display Device Including The Same, And Electronic Device Including The Same

(71) Applicants: Samsung Display Co., Ltd., Yongin-si (KR); Konkuk University Industrial Cooperation Corp, Seoul (KR)

(72) Inventors: Hee Ju Moon, Yongin-si (KR); Jung Suk Oh, Seoul (KR); Kee Chan Park, Seoul (KR); Nack Hyeon Keum, Yongin-si (KR); Jong Seok Woo, Yongin-si (KR); Sang Hun Kim, Yongin-si (KR)

(73) Assignees: Samsung Display Co., Ltd., Yongin-si (KR); Konkuk University Industrial Cooperation Corp, Seoul (KR)

(21) Appl. No.: 19/385,471

(22) Filed: Nov. 11, 2025

(30) Foreign Application Priority Data
Apr. 18, 2025 (KR) 10-2025-0051092

(51) Int. Cl. G09G 3/3266; G09G 3/3233; G11C 19/28

(52) U.S. Cl. CPC G09G 3/3266; G09G 3/3233; G09G 2300/0819; G09G 2300/0842; G09G 2300/0861; G09G 2310/0286; G09G 2320/0252; G09G 2330/021; G09G 2340/0435; G11C 19/28

(57) ABSTRACT

A stage circuit comprising an input part configured to connect between a second input terminal and a first node in response to a signal input to a first input terminal; a stabilizing part configured to connect between the first node and a second node in response to a voltage input to a third input terminal; and a first output part including a transistor that includes at least one N-type semiconductor controlled in response to a voltage applied to the second node, and configured to electrically connect a first output terminal and a third input terminal or electrically connect the first output terminal and a fifth input terminal.

### CROSS-REFERENCE TO RELATED APPLICATION

This application claims priority to and the benefit of Korean Patent Application No. 10-2025-0051092 filed in the Korean Intellectual Property Office on Apr. 18, 2025, the entire contents of which are incorporated herein by reference.

### TECHNICAL FIELD

Aspects of the present disclosure are related to a stage circuit, a display device including the same, and an electronic device including the same.

### BACKGROUND

With the development of information technology, the importance of a display device as a medium of connection between a user and information increases. In response to this, the use of display devices such as a liquid crystal display device, an organic light emitting display device, and the like is increasing.

The display device may include stage circuits for sequentially generating scan signals. The stage circuits may output a signal (e.g., an output signal). In order to output a signal at a stable level, it is desired to maintain a stable magnitude of a voltage applied to a node within the stage circuit.

### SUMMARY

The technical problem to be solved is to provide a stage circuit capable of reliably controlling an output signal, a display device including the same, and an electronic device including the same.

Aspects of the present disclosure may provide a stage circuit comprising an input part configured to connect between a second input terminal and a first node in response to a signal input to a first input terminal; a stabilizing part configured to connect between the first node and a second node in response to a voltage input to a third input terminal; and a first output part including a transistor that includes at least one N-type semiconductor controlled in response to a voltage applied to the second node, and configured to electrically connect a first output terminal and a third input terminal or electrically connect the first output terminal and a fifth input terminal.

The input part may include a first transistor including a gate electrode connected to the first input terminal and electrically connecting between the second input terminal and the first node.

The stabilizing part may include a second transistor including a gate electrode electrically connected to the third input terminal and electrically connecting between the first node and the first output part; and a third transistor including a gate electrode electrically connected to the third input terminal and electrically connecting between the first node and the second node.

The stage circuit may further comprise a second output part configured to control the second output terminal and the third input terminal to be electrically connected in response to a voltage applied to the second node, and configured to control the second output terminal and a fourth input terminal to be electrically connected in response to a voltage applied to the first output terminal.

The second output part may include a fourth transistor including a gate electrode electrically connected to the first output terminal and electrically connecting between the fourth input terminal and the second output terminal; a fifth transistor including a gate electrode electrically connected to the second node and electrically connecting between the third input terminal and the second output terminal; and a first capacitor having one electrode electrically connected to the second node and another electrode electrically connected to the second output terminal.

The second output part may further include a second capacitor having one electrode electrically connected to the second output terminal and another electrode electrically connected to a third node, and the third node may be connected to the stabilizing part and the first output part.

The first output part may include a sixth transistor including a gate electrode electrically connected to the stabilizing part and electrically connecting between the fifth input terminal and the first output terminal; and a seventh transistor including a gate electrode electrically connected to the second node and electrically connected between the third input terminal and the first output terminal. At least one of the sixth transistor and the seventh transistor may include an N-type semiconductor.

The sixth transistor and the seventh transistor may operate alternately in response to a voltage of the first node.

The sixth transistor and the seventh transistor may include different types of semiconductors.

The first output may include a sixth transistor configured to apply a high-level voltage to the first output terminal. The fourth transistor may be configured to be turned off in response to the high-level voltage applied to the first output terminal so that a low-level voltage is applied to the second output terminal.

The first output part may include a sixth transistor configured to apply a high-level voltage to the first output terminal. When a turn-on level voltage is applied to the first input terminal and when a low-level voltage is applied to the first node by connecting the first node to the second input terminal, the sixth transistor may be turned on to apply the high-level voltage to the first output terminal.

An output signal output from the first output terminal and a carry signal output from the second output terminal may be in inverse phase with each other.

Each of the first to sixth transistors may include a P-type semiconductor.

The first input terminal may be configured to receive a clock signal. In low frequency driving, the clock signal may have a low-level voltage.

The first output terminal may be connected to a pixel. The pixel may include a first pixel transistor including a gate electrode electrically connected to a first pixel node, and connected between a second pixel node and a third pixel node; a second pixel transistor electrically connecting between a data line and the third pixel node; a third pixel transistor including a gate electrode electrically connected to the first output terminal, and electrically connecting between the first pixel node and the second pixel node; and a fifth pixel transistor connected between a first power line and the third pixel node. In the low frequency driving, the third pixel transistor may be in a turn-off state.

The second input terminal may be configured to receive a start signal or a carry signal of a preceding stage circuit. The third input terminal may be configured to receive a low-level voltage. A fourth input terminal and the fifth input terminal may be configured to receive a high-level voltage. The first output terminal may be configured to output an output signal corresponding to a scan signal. The second output terminal may be configured to output a carry signal.

Aspects of the present disclosure may provide a display device comprising a display panel including a plurality of pixels, a plurality of scan lines connected to the plurality of pixels, and a plurality of data lines connected to the plurality of pixels; a scan drive circuit including a plurality of stage circuits configured to supply a scan signal to the plurality of scan lines; and a data drive circuit configured to supply a data signal to the plurality of data lines, wherein at least one of the plurality of stage circuits includes a first transistor including a gate electrode connected to a first input terminal, and electrically connected between a second input terminal and a first node; a second transistor including a gate electrode connected to a third input terminal, and connected to the first node; a third transistor including a gate electrode connected to the third input terminal, and electrically connecting between the first node and a second node; a fourth transistor including a gate electrode connected to a first output terminal, and electrically connecting between a fourth input terminal and a second output terminal, the first output terminal being configured to output the scan signal; a sixth transistor including a gate electrode connected to the second transistor, and electrically connecting between a fifth input terminal and the first output terminal; and a seventh transistor including a gate electrode connected to the second node, and electrically connecting between the third input terminal and the first output terminal, and wherein at least one of the sixth transistor and the seventh transistor includes an N-type semiconductor.

At least one of the plurality of pixels may include a first pixel transistor including a gate electrode connected to a first pixel node, and connected between a second pixel node and a third pixel node; a second pixel transistor including a gate electrode connected to a first sub-scan line, and electrically connecting between any one of the plurality of data lines and the third pixel node; and a third pixel transistor including a gate electrode connected to a second sub-scan line, electrically connecting between the first pixel node and the second pixel node in response to the scan signal, and including an N-type semiconductor.

Aspects of the present disclosure may provide an electronic device comprising a processor that outputs a control signal; and a display device including a timing controller configured to control a plurality of stage circuits to output a scan signal in response to the control signal, wherein at least one of the plurality of stage circuits includes a first transistor including a gate electrode connected to a first input terminal, and configured to switch an electrical connection between a second input terminal and a first node; a second transistor including a gate electrode connected to a third input terminal, and connected to the first node; a third transistor including a gate electrode connected to the third input terminal, and configured to switch an electrical connection between the first node and a second node; a fourth transistor including a gate electrode connected to a first output terminal, and configured to switch an electrical connection between a fourth input terminal and a second output terminal, the first output terminal being configured to output the scan signal; a fifth transistor including a gate electrode connected to the second node, and configured to switch an electrical connection between the third input terminal and the second output terminal; a sixth transistor including a gate electrode connected to the second transistor, and configured to switch an electrical connection between a fifth input terminal and the first output terminal; a seventh transistor including a gate electrode connected to the second node, and configured to switch an electrical connection between the third input terminal and the first output terminal; and a capacitor connected between the second node and the second output terminal, wherein at least one of the sixth transistor and the seventh transistor includes an N-type semiconductor.

The seventh transistor may include an N-type semiconductor.

### BRIEF DESCRIPTION OF THE DRAWINGS

FIG. 1 is a system block diagram of an electronic device according to aspects of the present disclosure.

FIG. 2A is an equivalent circuit diagram of a pixel according to an aspect of the present disclosure.

FIG. 2B is an equivalent circuit diagram of a pixel according to another aspect of the present disclosure.

FIG. 3 is a block diagram of a scan drive circuit according to aspects of the present disclosure.

FIG. 4 is an equivalent circuit diagram of a stage circuit according to an aspect.

FIG. 5 is an equivalent circuit diagram of a stage circuit according to another aspect.

FIG. 6 is an equivalent circuit diagram of a stage circuit according to another aspect.

FIG. 7 is a timing diagram of a driving method according to an aspect of a stage circuit.

FIGS. 8 to 12 are drawings illustrating a stage circuit according to the aspect of FIG. 6 in relation to the driving method of FIG. 7.

FIG. 13 is a timing diagram of a driving method according to an aspect during low frequency driving.

FIG. 14 is a diagram illustrating the stage circuit according to the aspect of FIG. 6 in relation to the driving method of FIG. 13.

FIG. 15 is a diagram comparing a voltage level of a second node with respect to a voltage level of an i-th output signal.

FIG. 16 is a block diagram of an electronic device according to an aspect of the present disclosure.

FIG. 17 is a schematic diagram of an electronic device according to various aspects.

### DETAILED DESCRIPTION

Hereinafter, with reference to the accompanying drawings, various aspects of the present disclosure will be described in detail to facilitate practice by one having ordinary skill in the art to which the present disclosure belongs. The present disclosure may be implemented in many different forms and is not limited to the aspects described herein.

In order to clearly illustrate the present disclosure, portions not pertinent to the description have been omitted, and identical or similar components have been designated by the same reference numerals throughout the specification. Accordingly, the aforementioned reference numerals may be used in other drawings.

Further, the size and thickness of each component shown in the drawings is arbitrarily indicated for ease of illustration and the present disclosure is not necessarily limited to that shown. Thicknesses may be exaggerated in the drawings to clearly represent the various layers and regions.

Also, when "the same" is used in the description, it may mean "substantially the same", i.e., the same as the extent that a person of ordinary skill would be led to believe that they are the same. Other expressions may also omit "substantially".

Terms such as "first", "second", and the like may be used to describe various components, but the components are not to be limited by such terms. These terms are used only for the purpose of distinguishing one component from another. For example, a first component may be named a second component, and similarly, a second component may be named a first component, without departing from the scope of the present disclosure. The singular expression includes the plural unless the context clearly indicates otherwise.

The terms "under", "below", "on", "above", and the like are used to describe the relationship of the configurations shown in the drawings. These terms are relative and are described with reference to the direction shown in the drawings.

Unless otherwise defined, all terms used herein (including technical and scientific terms) shall have the same meaning as commonly understood by those skilled in the art to which the present disclosure belongs. In addition, terms such as those defined in commonly used dictionaries are to be interpreted as having a meaning consistent with their meaning in the context of the relevant art and are expressly defined herein, unless interpreted in an idealized or overly formal sense.

The terms "comprise", "include", or "have" and the like are intended to designate the presence of the features, numbers, steps, actions, components, parts, or combinations thereof described in the specification and are not to be understood as precluding the possibility of the presence or addition of one or more other features, numbers, steps, actions, components, parts, or combinations thereof.

Aspects of the present disclosure will now be described in detail with reference to the accompanying drawings.

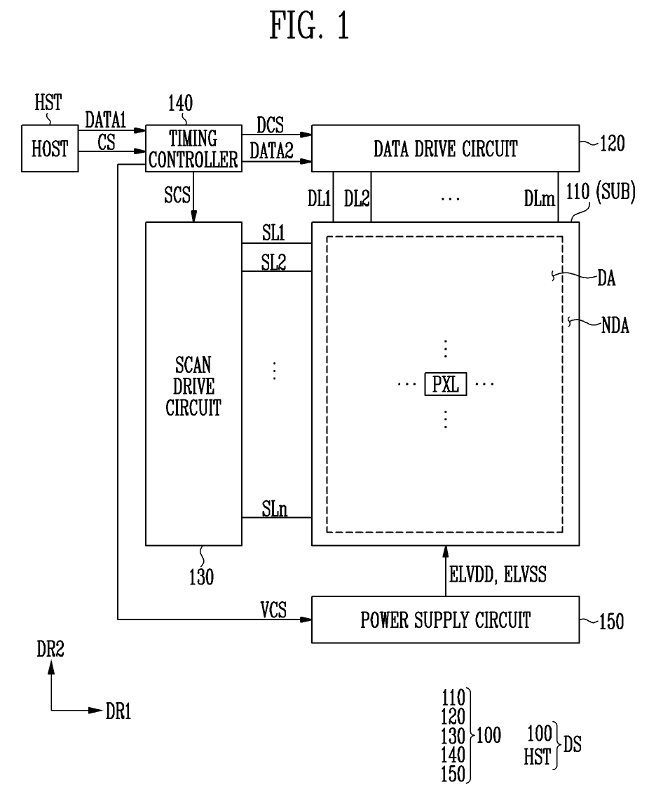

FIG. 1 is a system block diagram of an electronic device DS according to aspects of the present disclosure.

The electronic device DS according to aspects of the present disclosure may include a display device 100 and a host HST.

Referring to FIG. 1, the display device 100 according to aspects of the present disclosure may include a display panel 110, a data drive circuit 120, a scan drive circuit 130, a timing controller 140, and a power supply circuit 150.

The display panel 110 may include a substrate SUB. The display panel 110 may include a display area DA in which a plurality of pixels PXL are located on the substrate SUB, and a non-display area NDA surrounding the display area DA. In the display panel 110 (or the display area DA), a plurality of data lines DL1 to DLm (where m is an integer of 2 or more) and a plurality of scan lines SL1 to SLn (where n is an integer of 2 or more) electrically connected to the plurality of pixel PXL may be arranged. In the display panel 110, one or more power lines configured to apply power voltages ELVDD and ELVSS to the plurality of pixels PXL may be arranged. The non-display area NDA may be located in a peripheral area of the display area DA (e.g., an edge area of the display area DA). In the non-display area NDA, one or more pads may be located, and the plurality of data lines DL1 to DLm may be supplied with a data voltage, a power voltage, and the like.

The display panel 110 may be formed as a flat surface, but aspects of the present disclosure are not limited thereto. For example, the display panel 110 may include curved surfaces formed at the left and right ends. The curved surfaces may have a constant curvature, or may have a varying curvature. Additionally, the display panel 110 may be flexibly formed to be bent, curved, folded, or curled.

In an aspect, the substrate SUB may include a rigid glass substrate. However, aspects of the present disclosure are not limited thereto, and the substrate SUB may include a flexible plastic substrate. For example, the plastic substrate may be implemented as a polyimide (PI) substrate. In another aspect, the substrate SUB may be implemented as a silicon substrate.

The plurality of data lines DL1 to DLm may extend in one direction in the display panel 110. For example, the one direction may be a second direction DR2. The plurality of data lines DL1 to DLm may extend as a whole in the second direction DR2 in the display panel 110. For example, the second direction DR2 may be a direction across an upper side to a lower side of the display panel 110, but aspects of the present disclosure are not limited thereto.

The plurality of scan lines SL1 to SLn may extend in one direction in the display panel 110. For example, the one direction may be a first direction DR1. The plurality of scan lines SL1 to SLn may extend as a whole in the first direction DR1 in the display panel 110. The first direction DR1 may be different from the second direction DR2, but aspects of the present disclosure are not limited thereto. For example, the first direction DR1 may be a direction across a left side to a right side of the display panel 110.

The data drive circuit 120 may be configured to supply a data voltage to the plurality of data lines DL1 to DLm. The data drive circuit 120 may generate the data voltage based on second image data DATA2 and a data drive circuit control signal DCS, and may output the generated data voltage to the plurality of data lines DL1 to DLm in a timed manner. For example, the data drive circuit control signal DCS may include a source start pulse (SSP) signal, a source shift clock (SSC) signal, a source output enable (SOE) signal, and the like.

The data drive circuit 120 may be implemented as an integrated circuit (e.g., a source driver integrated circuit (SDIC)) formed separate from the display panel 110, or may be formed with the display panel 110 and formed on at least a portion of the non-display area NDA of the display panel 110.

The scan drive circuit 130 is configured to output a scan signal to the plurality of scan lines SL1 to SLn in response to a scan drive circuit control signal SCS. The scan drive circuit control signal SCS may include a start signal to indicate the start of a frame, a horizontal synchronization signal to output the scan signal in time with a timing of the data voltage being applied, and the like.

The scan drive circuit 130 may be implemented as an integrated circuit (e.g., a gate driving integrated circuit (GDIC)) formed separate from the display panel 110, or may be formed with the display panel 110 and formed in at least a portion of the non-display area NDA of the display panel 110.

The power supply circuit 150 may be configured to output a constant voltage. The power supply circuit 150 may output a power voltage (e.g., a first power voltage ELVDD, a second power voltage ELVSS, etc.) that is supplied to the display panel 110. According to aspects, the power supply circuit 150 may output a voltage (e.g., a high-level voltage, a low-level voltage, etc.) supplied to the scan drive circuit 130. According to aspects, the power supply circuit 150 may output a voltage (e.g., a gamma voltage, etc.) supplied to the data drive circuit 120. The power supply circuit 150 may include, for example, a regulator (e.g., a low dropout (LDO) regulator, etc.). The power supply circuit 150 may be implemented, for example, as a power management integrated circuit (PMIC). The power supply circuit 150 may be configured to output a power voltage to the power lines in response to a power supply circuit control signal VCS.

The timing controller 140 may be configured to control the data drive circuit 120, the scan drive circuit 130, the power supply circuit 150, and the like. The timing controller 140 may generate and output control signals DCS, SCS, and VCS for controlling the data drive circuit 120, the scan drive circuit 130, and the power supply circuit 150 based on a control signal CS (e.g., a synchronization signal, a clock signal, a data enable signal, etc.) input via the host HST. According to aspects, the timing controller 140 may generate a synchronization signal, a data enable signal, and the like therein based on the control signal CS input from the host HST (e.g., information about a drive frequency (or frame rate) of an image displayed on the display panel 110).

The timing controller 140 may receive first image data DATA1 from the host HST and may arrange the first image data DATA1 by pixel row. The timing controller 140 may convert the first image data DATA1 to meet a preset interface (e.g., low voltage differential signaling (LVDS), display port (DP), embedded display port (eDP), etc.). The second image data DATA2 output by the timing controller 140 to the data drive circuit 120 may be converted internally in the timing controller 140 according to the preset interface.

According to aspects, the timing controller 140 may be disposed within the display device 100 as a logic type. According to aspects, the timing controller 140 may be of a processor type and disposed within the display device 100. The timing controller 140 may include one or more memories (e.g., registers, etc.).

The host HST may include a set-top box, an application processor (AP), or the like. In an aspect, the host HST may be a configuration external to the display device 100 that is not included in the display device 100. In an aspect, the host HST may be mounted within the display device 100. Transmission and reception of the first image data DATA1 and the control signal CS may be accomplished via an interface between the host HST and the display device 100. The interface may be, for example, a serial programming interface (SPI), an inter integrated circuit (I2C), a mobile industry processor interface (MIPI), or the like. However, aspects of the present disclosure are not limited thereto.

In FIG. 1, the circuits that supply signals, voltages, and the like to the display panel 110 are merely categorized by function. For example, the data drive circuit 120 and the timing controller 140 may be formed within one integrated circuit. The data drive circuit 120 and the timing controller 140 may be categorized by function within one integrated circuit within the display device 100.

The display device 100 according to aspects of the present disclosure may be used as a display screen for a variety of products, including a television, a laptop, a monitor, a billboard, an Internet of Things (IoT) device, as well as portable electronic devices such as a mobile phone, a smart phone, a tablet personal computer, a smart watch, a watch phone, a mobile communication terminal, an electronic notebook, an e-book, a portable multimedia player (PMP), a navigation system, an ultra-mobile personal computer (UMPC), and the like.

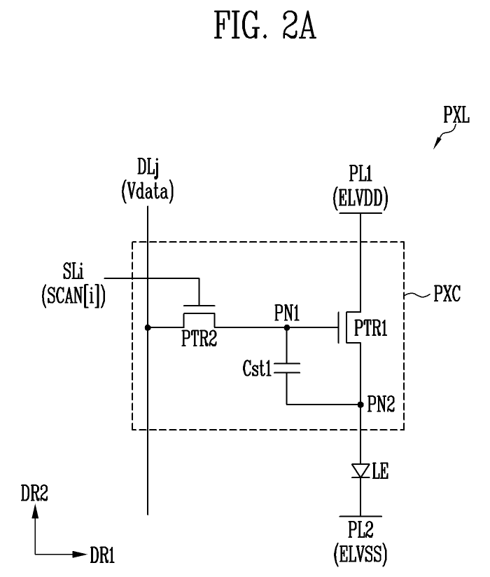

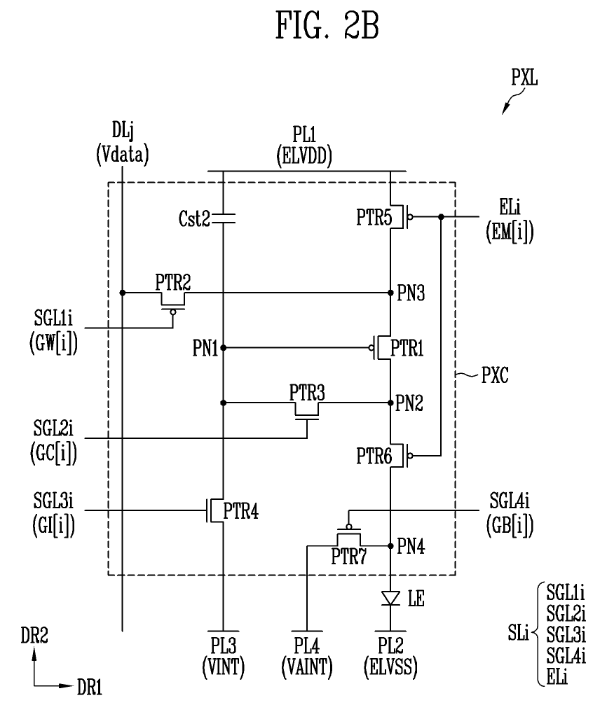

FIG. 2A is an equivalent circuit diagram of a pixel PXL according to an aspect of the present disclosure.

Referring to FIG. 2A, the pixel PXL according to aspects of the present disclosure may include a pixel drive circuit PXC and a light emitting element LE.

The pixel drive circuit PXC may include two or more switching elements and one or more storage elements. In an aspect, the switching element may be implemented as a transistor. In an aspect, the storage element may be implemented as a capacitor.

In an aspect, the transistor may be implemented as a bipolar junction transistor (BJT), a field effect transistor (FET), or the like, but aspects of the present disclosure are not limited thereto.

Referring to FIG. 2A, the pixel drive circuit PXC according to an aspect may include first and second pixel transistors PTR1 and PTR2 and a storage capacitor Cst1 (e.g., a first storage capacitor Cst1). However, according to aspects, the pixel drive circuit PXC may include three or more transistors, or may include two or more capacitors.

The first pixel transistor PTR1 may include a gate electrode electrically connected to a first pixel node PN1. The first pixel transistor PTR1 may include a first electrode (e.g., any one of a source electrode and a drain electrode) electrically connected to a first power line PL1, and a second electrode (e.g., another one of the source electrode and the drain electrode) electrically connected to the light emitting element LE. The first pixel transistor PTR1 may provide the light emitting element LE with a driving current corresponding to a voltage applied to the first pixel node PN1. The first power line PL1 may be applied with a first power voltage ELVDD. The first power voltage ELVDD may be a high potential voltage.

The second pixel transistor PTR2 may be configured to switch an electrical connection between a j-th data line DLj and the first pixel node PN1 in response to an i-th scan signal SCAN[i] (also referred as scan signal SCAN[i] below) applied to an i-th scan line SLi (where i is an integer greater than or equal to 1). When the second pixel transistor PTR2 is turned on in response to the scan signal SCAN[i] of a turn-on level (e.g., high-level), the pixel drive circuit PXC may be written with a data voltage Vdata. The data voltage Vdata or a voltage corresponding to the data voltage Vdata may be applied to the first pixel node PN1.

The storage capacitor Cst1 may include a first electrode electrically connected to the first pixel node PN1 and a second electrode electrically connected to a second pixel node PN2. The second pixel node PN2 may be a node electrically connected to the first pixel transistor PTR1 and the light emitting element LE. In an aspect, the first electrode and the second electrode may be located in the same layer of the substrate SUB (see FIG. 1). In another aspect, the first electrode and the second electrode may be located in different layers of the substrate SUB. In an aspect where the first electrode and the second electrode are located in different layers, the first electrode and the second electrode may be stacked perpendicular to each other. However, aspects of the present disclosure are not limited thereto.

The light emitting element LE may emit light in response to a driving current flowing through the first pixel transistor PTR1. The driving current may flow in a direction from the first power line PL1 to a second power line PL2. The light emitting element LE may include an anode electrode, a cathode electrode, and a light emitting layer. The anode electrode may be electrically connected to the first power line PL1. The cathode electrode may be electrically connected to the second power line PL2. The second power line PL2 may be applied with a second power voltage ELVSS. In an aspect, the light emitting layer may be located between the anode electrode and the cathode electrode. According to aspects, the light emitting layer may be implemented as an organic light emitting layer including an organic light emitting material. However, aspects of the present disclosure are not limited thereto, and the light emitting layer may include an inorganic light emitting material, a quantum dot, a nanorod, and the like. Referring to FIG. 2A, the anode electrode may be electrically connected to the second pixel node PN2.

Referring to FIG. 2A, the pixel drive circuit PXC according to aspects of the present disclosure may include a transistor including at least one N-type semiconductor. For example, at least one of the first pixel transistor PTR1 and the second pixel transistor PTR2 may be implemented as transistors including an N-type semiconductor. The transistor including an N-type semiconductor may be turned on in response to a high-level of voltage and turned off in response to a low-level of voltage.

On the other hand, the pixel PXL according to aspects of the present disclosure is not limited to a structure having two transistors and one capacitor. According to aspects, the scan signal SCAN[i] may be applied to a signal for controlling an emission timing of the light emitting element LE. According to aspects, the scan signal SCAN[i] may be applied to a signal for controlling a timing at which an initialization voltage is applied to the anode electrode of the light emitting element LE. According to aspects, the scan signal SCAN[i] may be applied to a signal for controlling a timing at which an initialization voltage is applied to a gate electrode of the first pixel transistor PTR1. According to aspects, the scan signal SCAN[i] may be applied to a signal for controlling a timing at which a bias voltage is applied to a source electrode of the first pixel transistor PTR1. However, aspects of the present disclosure are not limited thereto.

FIG. 2B is an equivalent circuit diagram of a pixel PXL according to another aspect of the present disclosure.

Referring to FIG. 2b, the pixel PXL according to aspects of the present disclosure may include a pixel drive circuit PXC and a light emitting element LE.

The pixel drive circuit PXC may be connected to a scan line SLi and a data line DLj.

The scan line SLi may include two or more sub-scan lines. Referring to FIG. 2B, the scan line SLi may include an i-th first sub-scan line SGL1i (also referred to as a first sub-scan line SGL1i), an i-th second sub-scan line SGL2i (also referred to as a second sub-scan line SGL2i), an i-th third sub-scan line SGL3i (also referred to as a third sub-scan line SGL3i), an i-th fourth sub-scan line SGL4i (also referred to as a fourth sub-scan line SGL4i), and an i-th emission control line ELi (also referred to as an emission control line ELi).

The pixel drive circuit PXC according to aspects of the present disclosure may include a plurality of switching elements. For example, the pixel drive circuit PXC according to aspects of the present disclosure may include first to seventh pixel transistors PTR1 to PTR7. The pixel drive circuit PXC according to aspects of the present disclosure may include at least one storage element. For example, the pixel drive circuit PXC according to aspects of the present disclosure may include a storage capacitor Cst2 (or a second storage capacitor Cst2).

The first pixel transistor PTR1 may be configured to control the magnitude of current (e.g., driving current) supplied to the light emitting element LE. The first pixel transistor PTR1 may include a gate electrode connected to a first pixel node PN1. The first pixel transistor PTR1 may include a first electrode (e.g., any one of a source electrode and a drain electrode) connected to a second pixel node PN2 and a second electrode (e.g., another one of the source electrode and the drain electrode) connected to a third pixel node PN3. Depending on the magnitude of the voltage applied to the first pixel node PN1, the magnitude of the current (e.g., driving current, or drain current) flowing through the first pixel transistor PTR1 may be determined. The first pixel transistor PTR1 may be referred to as a drive transistor.

The second pixel transistor PTR2 may be configured to write a data voltage Vdata to the pixel drive circuit PXC. The second pixel transistor PTR2 may be configured to switch an electrical connection between a data line DLj and the third pixel node PN3. The second pixel transistor PTR2 may include a gate electrode connected to the first sub-scan line SGL1i. The second pixel transistor PTR2 may be electrically connected between the data line DLj and the third pixel node PN3 in response to a first scan signal GW[i] (e.g., a first scan signal GW[i] of a turn-on level) applied to the first sub-scan line SGL1i. The second pixel transistor PTR2 may be referred to as a scan transistor.

The third pixel transistor PTR3 may be configured to switch an electrical connection between the first pixel node PN1 and the second pixel node PN2. The third pixel transistor PTR3 may be configured to compensate for a change in the characteristic value of the first pixel transistor PTR1 (e.g., a change in a threshold voltage). The third pixel transistor PTR3 may include a gate electrode connected to the second sub-scan line SGL2i. The third pixel transistor PTR3 may be electrically connected between the first pixel node PN1 and the second pixel node PN2 in response to a second scan signal GC[i] (e.g., a second scan signal GC[i] of a turn-on level) applied to the second sub-scan line SGL2i. When the third pixel transistor PTR3 is turned on, the first pixel transistor PTR1 may be diode-connected. The third pixel transistor PTR3 may be referred to as a compensation transistor.

The fourth pixel transistor PTR4 may be configured to switch an electrical connection between the first pixel node PN1 and a third power line PL3. The fourth pixel transistor PTR4 may include a gate electrode connected to the third sub-scan line SGL3i. The fourth pixel transistor PTR4 may be electrically connected between the first pixel node PN1 and the third power line PL3 in response to a third scan signal GI[i] (e.g., a third scan signal GI[i] of a turn-on level) applied to the third sub-scan line SGL3i. When the fourth pixel transistor PTR4 is turned on, the first pixel node PN1 may be applied with a first initialization voltage VINT that is applied to the third power line PL3. The fourth pixel transistor PTR4 may be referred to as a first initialization transistor.

The fifth pixel transistor PTR5 may be configured to switch an electrical connection between the first power line PL1 and the third pixel node PN3. The fifth pixel transistor PTR5 may include a gate electrode connected to the emission control line ELi. The fifth pixel transistor PTR5 may be electrically connected between the first power line PL1 and the third pixel node PN3 in response to an emission control signal EM[i] (e.g., an emission control signal EM[i] of a turn-on level) applied to the emission control line ELi. When the fifth pixel transistor PTR5 is turned on, the third pixel node PN3 may be applied with the first power voltage ELVDD applied to the first power line PL1. The fifth pixel transistor PTR5 may be referred to as a first emission control transistor.

The sixth pixel transistor PTR6 may be configured to switch an electrical connection between the second pixel node PN2 and a fourth pixel node PN4. The sixth pixel transistor PTR6 may include a gate electrode connected to the emission control line ELi. The sixth pixel transistor PTR6 may be electrically connected between the second pixel node PN2 and the fourth pixel node PN4 in response to the emission control signal EM[i] (e.g., the emission control signal EM[i] of a turn-on level) applied to the emission control line ELi. When the sixth pixel transistor PTR6 is turned on, an electrical connection may be made between the second pixel node PN2 and the fourth pixel node PN4. The sixth pixel transistor PTR6 may be referred to as a second emission control transistor.

The seventh pixel transistor PTR7 may be configured to switch an electrical connection between the fourth pixel node PN4 and a fourth power line PL4. The seventh pixel transistor PTR7 may include a gate electrode connected to the fourth sub-scan line SGL4i. The seventh pixel transistor PTR7 may be electrically connected between the fourth pixel node PN4 and the fourth power line PL4 in response to a fourth scan signal GB[i] (e.g., a fourth scan signal GB[i] of a turn-on level) applied to the fourth sub-scan line SGL4i. When the seventh pixel transistor PTR7 is turned on, the fourth pixel node PN4 may be applied with a second initialization voltage VAINT that is applied to the fourth power line PL4. The seventh pixel transistor PTR7 may be referred to as a second initialization transistor.

The storage capacitor Cst2 (or the second storage capacitor Cst2) may be configured to maintain the magnitude of a voltage applied to the first pixel node PN1. The storage capacitor Cst2 may include a one electrode connected to the first power line PL1 and another electrode connected to the second pixel node PN2. The storage capacitor Cst2 may be configured to maintain a potential difference between the first pixel node PN1 and the first power line PL1.

The light emitting element LE may include a first electrode connected to the fourth pixel node PN4, a second electrode connected to the second power line PL2, and a light emitting layer located between the first electrode and the second electrode. The first electrode may be any one (e.g., an anode electrode) of an anode electrode and a cathode electrode. The second electrode may be another one (e.g., a cathode electrode) of the anode electrode and the cathode electrode. The first electrode (e.g., an anode electrode) of the light emitting element LE may be connected to the first power line PL1 via the pixel drive circuit PXC. The second electrode (e.g., a cathode electrode) of the light emitting element LE may be connected to the second power line PL2 to which the second power voltage ELVSS may be applied. The second supply voltage ELVSS may have a ground potential, or may have a low potential voltage.

Transistors according to aspects of the present disclosure may include transistors including a P-type semiconductor and transistors including a N-type semiconductor. For example, the first, second, and fifth to seventh pixel transistors PTR1, PTR2, PTR5, PTR6, and PTR7 may be implemented as transistors including a P-type semiconductor. The third and fourth pixel transistors PTR3 and PTR4 may be implemented as transistors including an N-type semiconductor.

A transistor including a P-type semiconductor may be turned on in response to a low-level signal and turned off in response to a high-level signal. A transistor including an N-type semiconductor may be turned on in response to a high-level signal and turned off in response to a low-level signal.

It is known that a transistor including an N-type semiconductor has a relatively small magnitude of leakage current compared to a transistor including a P-type semiconductor. For example, by configuring the pixel PXL so that the third and fourth pixel transistors PTR3 and PTR4 of FIG. 2b include an N-type semiconductor, the magnitude of the voltage applied to the first pixel node PN1 may be maintained for a relatively long period of time (e.g., about 1 second). Thereby, images may be displayed at various refresh frame rates.

On the other hand, in a driving process for transistors including an N-type semiconductor (e.g., the second pixel transistor PTR2 in FIG. 2a, the third and fourth pixel transistors PTR3 and PTR4 in FIG. 2b), the scan signal for controlling them may have a low-level (or a turn-off level) for a relatively long time. The design of a scan drive circuit 130 (see FIG. 1) is required to stably output the scan signal of a low-level is required.

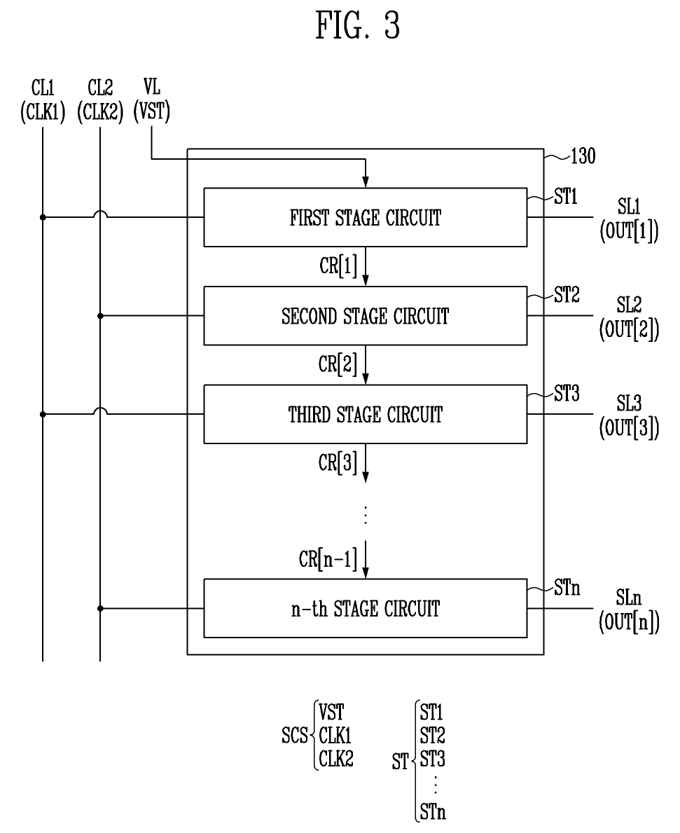

FIG. 3 is a block diagram of a scan drive circuit 130 according to aspects of the present disclosure.

Referring to FIG. 3, the scan drive circuit 130 according to aspects of the present disclosure may include stage circuits ST.

In an aspect, the stage circuits ST may include first to n-th stage circuit ST1, ST2, ST3, ..., and STn (hereinafter, ST1 to STn).

The first to nth stage circuits ST1 to STn may be connected to any corresponding one among first to n-th scan lines SL1 to SLn. The first to n-th stage circuits ST1 to STn may output any corresponding one of first to n-th output signals OUT[1], OUT[2], OUT[3], ..., and OUT[n] (hereinafter, OUT[1] to OUT[n]).

The first to n-th output signals OUT[1] to OUT[n] may have a turn-on level or a turn-off level. In an aspect, the turn-on level may be a high-level. The turn-off level may be a low-level.

Referring to FIG. 2A described above, any one among the first to n-th output signals OUT[1] to OUT[n] may correspond to the scan signal SCAN[i].

Referring to FIG. 2B described above, any one of the first to n-th output signals OUT[1] to OUT[n] may correspond to the second scan signal GC[i] or the third scan signal GI[i].

The scan drive circuit 130 may be connected to a first clock line CL1, a second clock line CL2, and a start line VL. The first clock line CL1 may be applied with a first clock signal CLK1. The second clock line CL2 may be applied with a second clock signal CLK2. A start signal VST may be applied to the start line VL. The first clock signal CLK1, the second clock signal CLK2, and the start signal VST may be included in a scan drive circuit control signal SCS.

In an aspect, the first stage circuit ST1 may be electrically connected to the first clock line CL1 and the start line VL. The first stage circuit ST1 may output the first output signal OUT[1] to the first scan line SL1. The first stage circuit ST1 may output a first carry signal CR[1].

In an aspect, the second stage circuit ST2 may be electrically connected to the second clock line CL2. The second stage circuit ST2 may receive the first carry signal CR[1] from the first stage circuit ST1. The second stage circuit ST2 may output the second output signal OUT[2] to the second scan line SL2. The second stage circuit ST2 may output a second carry signal CR[2].

In an aspect, the third stage circuit ST3 may be electrically connected to the first clock line CL1. The third stage circuit ST3 may receive the second carry signal CR[2] from the second stage circuit ST2. The third stage circuit ST3 may output the third output signal OUT[3] to the third scan line SL3. The third stage circuit ST3 may output a third carry signal CR[3].

In an aspect, the n-th stage circuit STn may be electrically connected to the second clock line CL2. The n-th stage circuit STn may receive a (n-1)-th carry signal CR[n-1] from a (n-1)-th stage circuit. The n-th stage circuit STn may output a n-th output signal OUT[n] to the n-th scan line SLn.

In an aspect, odd numbered stage circuits among the first to n-th stage circuits ST1 to STn may be electrically connected to the first clock line CL1. In an aspect, even-numbered stage circuits among the first to n-th stage circuits ST1 to STn may be electrically connected to the second clock line CL2.

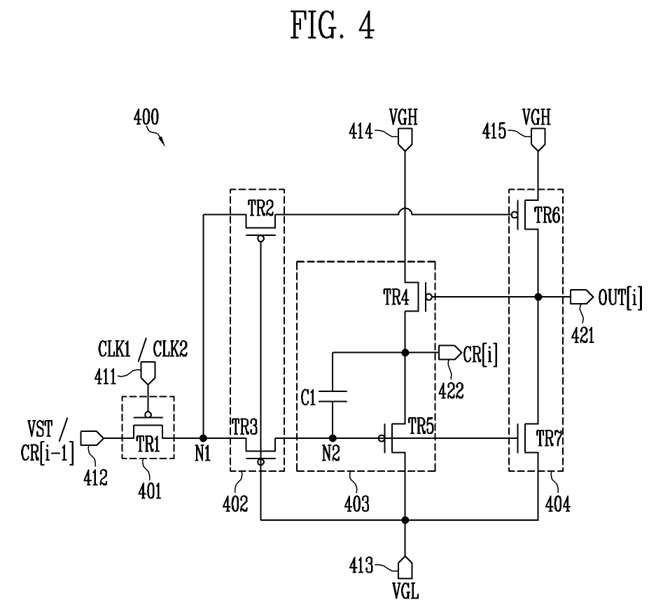

FIG. 4 is an equivalent circuit diagram of a stage circuit 400 according to an aspect.

The stage circuit 400 of FIG. 4 may be applied to any one of the first to n-th stage circuits ST1 to STn of FIG. 3. For example, the stage circuit 400 of FIG. 4 may be applied to an i-th stage circuit (where i is an integer greater than or equal to 1).

Referring to FIG. 4, the stage circuit 400 according to aspects of the present disclosure may include a plurality of switching elements and at least one storage element.

A switching element may be implemented as a transistor. A storage element may be implemented as a capacitor.

In an aspect, the stage circuit 400 according to aspects of the present disclosure may include an input part 401 (or input circuit 401), a stabilization part 402 (or stabilization circuit 402), a first output part 404 (or first output circuit 404), and a second output part 403 (or second output circuit 403).

The input part 401 may be connected between a second input terminal 412 and a first node N1 in response to a signal input to a first input terminal 411.

The stabilization part 402 may be connected between the first node N1 and a second node N2. The stabilization part 402 may be connected between the first node N1 and the first output part 404. The stabilization part 402 may be connected to a third input terminal 413. The stabilization part 402 may be controlled in response to a voltage applied to the third input terminal 413.

The first output part 404 may be controlled in response to a voltage applied to the second node N2 (or the first node N1). The first output part 404 may electrically connect a first output terminal 421 and the third input terminal 413, or electrically connect the first output terminal 421 and a fifth input terminal 415, in response to a voltage applied to the second node N2. The first output part 404 may supply a low-level voltage VGL or may supply a high-level voltage VGH, to the first output terminal 421 in response to a voltage applied to the second node N2.

The second output part 403 may be controlled in response to voltages applied to the second node N2 and the first output terminal 421. The second output part 403 may electrically connect a second output terminal 422 and the third input terminal 413 in response to a voltage applied to the second node N2. The second output part 403 may electrically connect the second output terminal 422 and a fourth input terminal 414 in response to a voltage applied to the first output terminal 421. The second output part 403 may supply a low-level voltage VGL to the second output terminal 422 in response to a voltage applied to the second node N2. The second output part 403 may supply a high-level voltage VGH to the second output terminal 422 in response to a voltage applied to the first output terminal 421.

In an aspect, the first output part 404 may include at least one transistor including an N-type semiconductor. The first output part 404 may include at least two transistors including different types of semiconductors. For example, the first output part 404 may include at least one transistor including an N-type semiconductor and at least one transistor including a P-type semiconductor.

Referring to FIG. 4, the stage circuit 400 according to an aspect may include seven transistors and one capacitor. In an aspect, the input part 401 may include a first transistor TR1. The stabilization part 402 may include a second transistor TR2 and a third transistor TR3. The second output part 403 may include a fourth transistor TR4, a fifth transistor TR5, and a first capacitor C1. The first output part 404 may include a sixth transistor TR6 and a seventh transistor TR7.

The first transistor TR1 may include a gate electrode electrically connected to the first input terminal 411. The first transistor TR1 may be configured to switch an electrical connection between the second input terminal 412 and the first node N1. A first clock signal CLK1 or a second clock signal CLK2 may be input to the first input terminal 411. A start signal VST or an (i-1)-th carry signal CR[i-1] may be input to the second input terminal 412. In an aspect, a turn-on level of the first transistor TR1 may be a low-level. In the aspect, the first transistor TR1 may be turned on in response to the first clock signal CLK1 of a low-level or the second clock signal CLK2 of a low-level. When the first transistor TR1 is turned on, the second input terminal 412 and the first node N1 may be electrically connected.

The second transistor TR2 may include a gate electrode electrically connected to the third input terminal 413. A low-level voltage VGL may be applied to the third input terminal 413. The second transistor TR2 may be configured to switch an electrical connection between the first node N1 and a gate electrode of the sixth transistor TR6. The second transistor TR2 may be turned on in response to the low-level voltage VGL. When the second transistor TR2 is turned on, a gate electrode of the sixth transistor TR6 and the first node N1 may be electrically connected.

The third transistor TR3 may include a gate electrode electrically connected to the third input terminal 413. The third transistor TR3 may be configured to switch an electrical connection between the first node N1 and the second node N2. The third transistor TR3 may be turned on in response to a low-level voltage VGL. When the third transistor TR3 is turned on, the first node N1 and the second node N2 may be electrically connected. The third transistor TR3 may be turned on together (e.g., simultaneously) with the second transistor TR2.

The fourth transistor TR4 may include a gate electrode electrically connected to the first output terminal 421. An i-th output signal OUT[i] may be applied to the first output terminal 421. The fourth transistor TR4 may be configured to switch an electrical connection between the fourth input terminal 414 and the second output terminal 422. A high-level voltage VGH may be applied to the fourth input terminal 414. The fourth transistor TR4 may be turned on in response to a low-level voltage VGL. When the fourth transistor TR4 is turned on, the second output terminal 422 may be electrically connected to the fourth input terminal 414. The fourth transistor TR4 may function as a pull-up transistor for an i-th carry signal CR[i]. The fourth transistor TR4 may be referred to as a first pull-up transistor.

In aspects of the present disclosure, the first output terminal 421 may function as a control node for controlling a voltage level of the i-th carry signal CR[i]. A specific description will be provided later.

The fifth transistor TR5 may include a gate electrode electrically connected to the second node N2. The fifth transistor TR5 may be configured to switch an electrical connection between the third input terminal 413 and the second output terminal 422 in response to a voltage applied to the second node N2. The fifth transistor TR5 may be turned on in response to a voltage of a low-level (e.g., a low-level voltage VGL). When the fifth transistor TR5 is turned on, the i-th carry signal CR[i] may have a low-level voltage VGL. The fifth transistor TR5 may function as a pull-down transistor for the i-th carry signal CR[i]. The fifth transistor TR5 may be referred to as a first pull-down transistor.

The sixth transistor TR6 may include a gate electrode electrically connected to the second transistor TR2. The sixth transistor TR6 may be configured to switch an electrical connection between the fifth input terminal 415 and the first output terminal 421. A high-level voltage VGH may be applied to the fifth input terminal 415. In an aspect, the fifth input terminal 415 may be integral with the fourth input terminal 414. The sixth transistor TR6 may be turned on in response to a voltage of a low-level (e.g., a low-level voltage VGL). When the sixth transistor TR6 is turned on, the i-th output signal OUT[i] may have a high-level voltage VGH. The sixth transistor TR6 may function as a pull-up transistor for the i-th output signal OUT[i]. The sixth transistor TR6 may be referred to as a second pull-up transistor.

The seventh transistor TR7 may include a gate electrode electrically connected to the second node N2. The seventh transistor TR7 may be configured to switch an electrical connection between the third input terminal 413 and the first output terminal 421. The seventh transistor TR7 may be turned on in response to a voltage of a high-level (e.g., a high-level voltage VGH). When the seventh transistor TR7 is turned on, the i-th output signal OUT[i] may have a low-level voltage VGL. The seventh transistor TR7 may function as a pull-down transistor for the i-th output signal OUT[i]. The seventh transistor TR7 may be referred to as a second pull-down transistor.

In aspects of the present disclosure, the i-th output signal OUT[i] output through the first output terminal 421 and the i-th carry signal CR[i] output through the second output terminal 422 may have phases reversed from each other. For example, while the i-th output signal OUT[i] has a low-level voltage VGL, the i-th carry signal CR[i] may have a high-level voltage VGH. While the i-th output signal OUT[i] has a high-level voltage VGH, the i-th carry signal CR[i] may have a low-level voltage VGL.

In aspects of the present disclosure, the control nodes (e.g., a first pull-up node and a first pull-down node) for controlling the voltage level of the i-th output signal OUT[i] may be a gate electrode of the sixth transistor TR6 and the second node N2, respectively. The control nodes (e.g., a second pull-up node and a second pull-down node) for controlling the voltage level of the i-th carry signal CR[i] may be the first output terminal 421 and the second node N2, respectively.

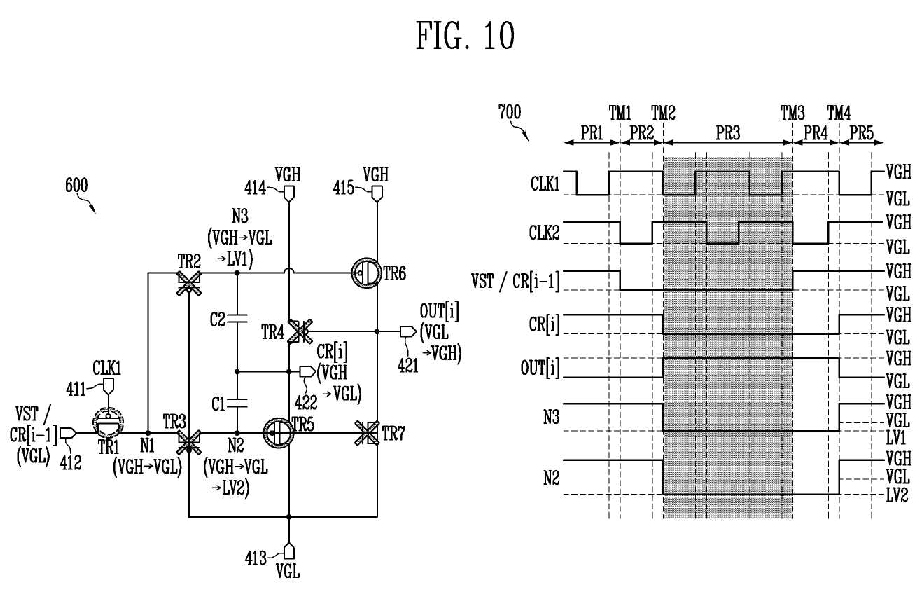

The first capacitor C1 may include one electrode connected to the second node N2 and another electrode connected to the second output terminal 422. The first capacitor C1 may be configured to maintain a potential difference between the second output terminal 422 and the second node N2. The first capacitor C1 may reflect a voltage drop at the second output terminal 422 to the second node N2, thereby reducing the voltage of the second node N2 to a level lower than the low-level voltage VGL. As the voltage level of the second node N2 is dropped to a level lower than the low-level voltage VGL by the first capacitor C1, a voltage of a level lower than the low-level voltage VGL may be applied to a gate electrode of the seventh transistor TR7. Thereby, for the seventh transistor TR7 including an N-type semiconductor, the voltage difference (i.e., "Vgs") between a gate electrode and a source electrode may be controlled to be less than zero. Accordingly, the seventh transistor TR7 may be reliably turned off. The first capacitor C1 may function as a boosting capacitor. The first capacitor C1 may be referred to as a boosting capacitor (or a first boosting capacitor). In aspects of the present disclosure, a process by which the voltage level of the second node N2 is reduced below the low-level voltage VGL is described in detail with reference to FIG. 10.

In aspects of the present disclosure, the first to sixth transistors TR1 to TR6 may be implemented as transistors including a P-type semiconductor. In an aspect, the first to sixth transistors TR1 to TR6 may be implemented as PMOS transistors with a metal-oxide-semiconductor (MOS) structure having a P-type channel. In an aspect, the first to sixth transistors TR1 to TR6 may be implemented as transistors using silicon as an active layer, such as amorphous silicon (a-Si), low-temperature polycrystalline silicon (LTPS), or the like.

In aspects of the present disclosure, the seventh transistor TR7 may be implemented as a transistor including an N-type semiconductor channel. In an aspect, the seventh transistor TR7 may be implemented as an NMOS transistor having an N-type channel. In an aspect, the seventh transistor TR7 may be implemented as a transistor using a metal oxide semiconductor (e.g., Indium Gallium Zinc Oxide (IGZO)) as an active layer.

In an aspect, semiconductor layers of the first to sixth transistors TR1 to TR6 and a semiconductor layer of the seventh transistor TR7 may be disposed in different layers. However, aspects of the present disclosure are not limited thereto.

In an aspect, the seventh transistor TR7 may be implemented as a single gate structure.

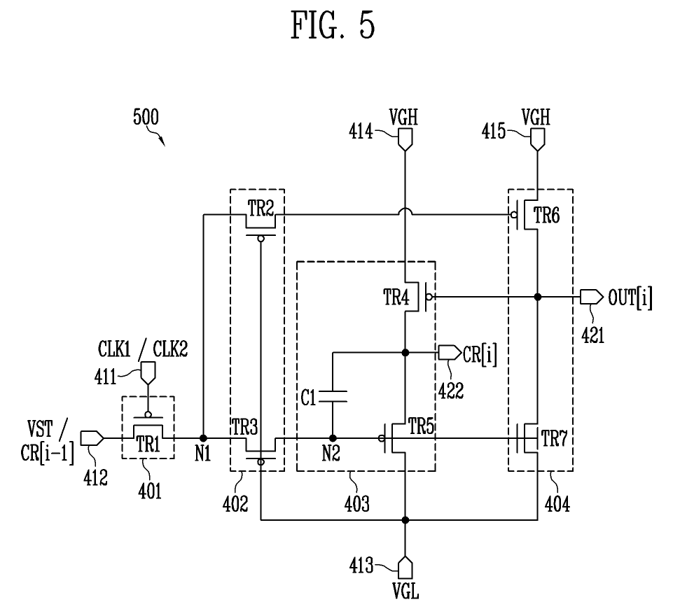

FIG. 5 is an equivalent circuit diagram of a stage circuit 500 according to another aspect.

Compared to the stage circuit 400 of FIG. 4, the stage circuit 500 of FIG. 5 may have the seventh transistor TR7 implemented as a double gate structure. In the aspect, the seventh transistor TR7 may include two channels formed on one surface and another surface of an N-type semiconductor layer, respectively. In the aspect, the seventh transistor TR7 may include two gate electrodes positioned correspondingly on the one surface and the another surface of the N-type semiconductor layer, respectively. The gate electrodes of the seventh transistor TR7 may be connected in common to the second node N2.

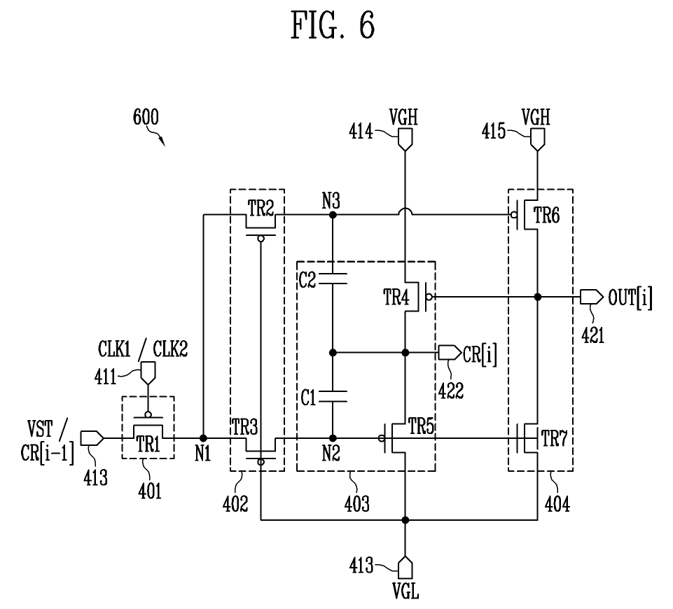

FIG. 6 is an equivalent circuit diagram of a stage circuit 600 according to another aspect.

Compared to the stage circuit 500 of FIGS. 4 and 5, the stage circuit 600 of FIG. 6 may further include a second capacitor C2.

In an aspect, the second output part 403 may further include the second capacitor C2. In the aspect, the stabilization part 402 may connect between the first node N1 and the second node N2, and may connect between the first node N1 and the third node N3. The stabilization part 402 may connect between the first node N1 and the first output part 404. The first output part 404 may be controlled in response to voltages applied to the second node N2 and the third node N3. The first output part 404 may electrically connect between the first output terminal 421 and the third input terminal 413 in response to a voltage applied to the second node N2. The first output part 404 may electrically connect between the first output terminal 421 and the fifth input terminal 415 in response to a voltage applied to the third node N3.

The second capacitor C2 may include one electrode electrically connected to the second output terminal 422 and another electrode electrically connected to the third node N3. The third node N3 may be connected to the second transistor TR2. The third node N3 may be connected to a gate electrode of the sixth transistor TR6. The second capacitor C2 may be configured to maintain a potential difference between the third node N3 and the second output terminal 422. The second capacitor C2 may reflect a voltage drop at the second output terminal 422 to the third node N3, thereby reducing the voltage of the third node N3 to a level lower than the low-level voltage VGL. As the voltage level of the third node N3 is lowered to a level lower than the low-level voltage VGL by the second capacitor C2, a voltage of a level lower than the low-level voltage VGL may be applied to the gate electrode of the sixth transistor TR6. Thereby, a stable turn-on level voltage may be supplied to the sixth transistor TR6 including a P-type semiconductor. The second capacitor C2 may function as a boosting capacitor. The second capacitor C2 may be referred to as a boosting capacitor (or a second boosting capacitor). In aspects of the present disclosure, a process by which the voltage level of the third node N3 is reduced below the low-level voltage VGL is described in detail with reference to FIG. 10.

On the other hand, the second capacitor C2 may mitigate the adverse effect of a voltage change of the first clock signal CLK1 or the second clock signal CLK2 affecting the voltage of the third node N3 due to a parasitic capacitor formed between the first input terminal 411 and the third node N3. Thereby, the second capacitor C2 may function as a stabilizing capacitor that controls the sixth transistor TR6 to maintain a stable turn-on state.

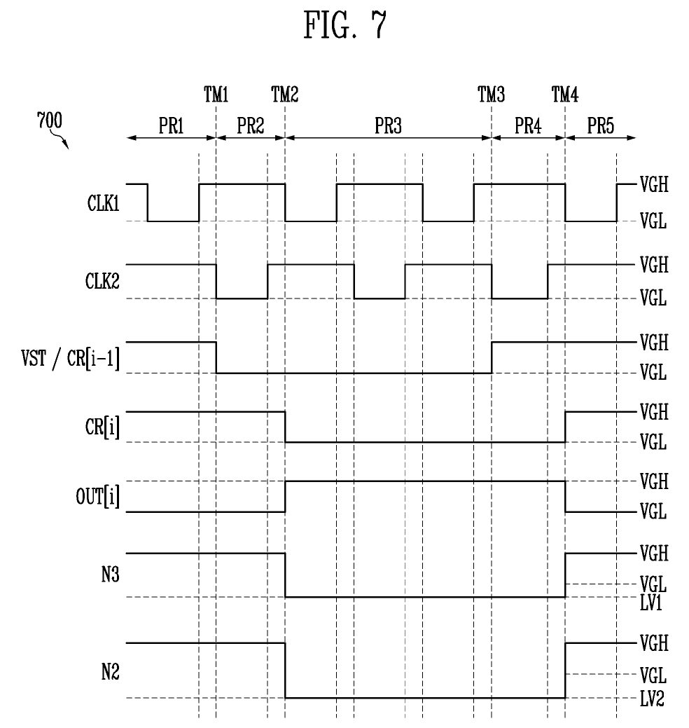

FIG. 7 is a timing diagram of a driving method 700 according to an aspect of a stage circuit.

The driving method 700 may be referred to as a driving method 700 of a stage circuit, a driving method 700 of a display device, a driving method 700 of an electronic device, or the like.

The driving method 700 of FIG. 7 is described with reference to the stage circuit 600 of FIG. 6. However, aspects of the present disclosure are not limited thereto. For example, if the driving method 700 is applied to the aspects of FIGS. 5 and 6, a description of the third node N3 may be replaced with a description of the i-th carry signal CR[i].

Referring to FIG. 7, the driving method 700 may include a first period PR1, a second period PR2, a third period PR3, a fourth period PR4, and a fifth period PR5.

The first period PR1 may be a period before a first time point TM1. The second period PR2 may be a period between the first time point TM1 and a second time point TM2. The third period PR3 may be a period between the second time point TM2 and a third time point TM3. The fourth period PR4 may be a period between the third time point TM3 and a fourth time point TM4. The fifth period PR5 may be a period after the fourth time point TM4.

In the first period PR1, the first clock signal CLK1 and the second clock signal CLK2 may toggle between a high-level voltage VGH and a low-level voltage VGL. The start signal VST or the (i-1)-th carry signal CR[i-1] may have a high-level voltage VGH. The i-th carry signal CR[i] may have a high-level voltage VGH. The i-th output signal OUT[i] may have a low-level voltage VGL. The third node N3 may have a high-level voltage VGH. The second node N2 may have a high-level voltage VGH.

In the second period PR2, the first clock signal CLK1 may have a high-level voltage VGH. The second clock signal CLK2 may have a low-level voltage VGL or a high-level voltage VGH. The start signal VST or the (i-1)-th carry signal CR[i-1] may have a low-level voltage VGL. The i-th carry signal CR[i] may have a high-level voltage VGH. The i-th output signal OUT[i] may have a low-level voltage VGL. The third node N3 may have a high-level voltage VGH. The second node N2 may have a high-level voltage VGH.

In the third period PR3, the first clock signal CLK1 and the second clock signal CLK2 may be toggled. The start signal VST or the (i-1)-th carry signal CR[i-1] may have a low-level voltage VGL. The i-th carry signal CR[i] may have a low-level voltage VGL. The i-th output signal OUT[i] may have a high-level voltage VGH. The third node N3 may have a first level voltage LV1. The second node N2 may have a second level voltage LV2.

The first level voltage LV1 may be lower than the low-level voltage VGL. The second level voltage LV2 may be lower than the low-level voltage VGL. In an aspect, the second level voltage LV2 may be lower than the first level voltage LV1. In another aspect, the first level voltage LV1 may be lower than the second level voltage LV2.

In the fourth period PR4, the first clock signal CLK1 may have a high-level voltage VGH. The second clock signal CLK2 may have a low-level voltage VGL or a high-level voltage VGH. The start signal VST or the (i-1)-th carry signal CR[i-1] may have a high-level voltage VGH. The i-th carry signal CR[i] may have a low-level voltage VGL. The i-th output signal OUT[i] may have a high-level voltage VGH. The third node N3 may have a first level voltage LV1. The second node N2 may have a second level voltage LV2.

In the fifth period PR5, the first clock signal CLK1 and the second clock signal CLK2 may be toggled. The start signal VST or the (i-1)-th carry signal CR[i-1] may have a high-level voltage VGH. The i-th carry signal CR[i] may have a high-level voltage VGH. The i-th output signal OUT[i] may have a low-level voltage VGL. The third node N3 may have a high-level voltage VGH. The second node N2 may have a high-level voltage VGH.

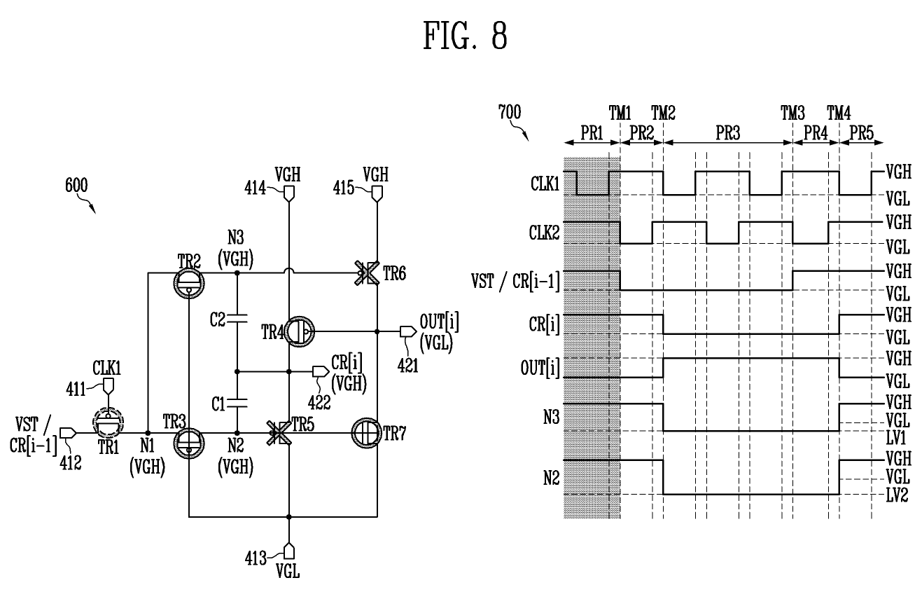

FIGS. 8 to 12 are drawings illustrating a stage circuit 600 according to the aspect of FIG. 6 in relation to the driving method 700 of FIG. 7.

For simplicity of explanation, it is assumed that the first clock signal CLK1 is input to a gate electrode of the first transistor TR1.

Referring to FIG. 8, the first period PR1 is described.

In the first period PR1, the first transistor TR1 may be controlled in response to the first clock signal CLK1. The first node N1 may be electrically connected to the second input terminal 412, and a high-level voltage VGH may be applied to the first node N1.

The second transistor TR2 and the third transistor TR3 may be turned on in response to a low-level voltage VGL applied to the third input terminal 413. The second node N2 and the third node N3 may be electrically connected to the first node N1 such that a high-level voltage VGH may be applied.

The fifth transistor TR5 may be turned off in response to a high-level voltage VGH applied to the second node N2.

The sixth transistor TR6 may be turned off in response to a high-level voltage VGH applied to the third node N3.

The seventh transistor TR7 may be turned on in response to a high-level voltage VGH applied to the second node N2. A low-level voltage VGL may be applied to the first output terminal 421.

The fourth transistor TR4 may be turned on in response to a low-level voltage VGL applied to the first output terminal 421. The second output terminal 422 may be electrically connected to the fourth input terminal 414, and the i-th carry signal CR[i] may have a high-level voltage VGH.

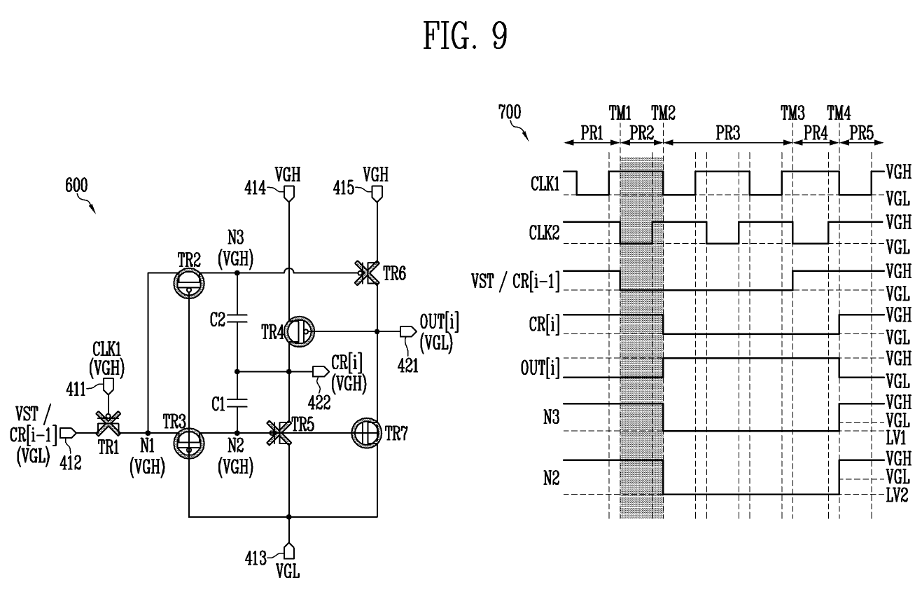

Referring to FIG. 9, the second period PR2 is described.

In the second period PR2, the first transistor TR1 may be turned off in response to a high-level voltage VGH applied to the first input terminal 411. The first node N1 may be isolated from the second input terminal 412. A high-level voltage VGH may be applied to the first node N1.

The second transistor TR2 and the third transistor TR3 may be turned on in response to a low-level voltage VGL applied to the third input terminal 413. The second node N2 and the third node N3 may be electrically connected to the first node N1 such that a high-level voltage VGH may be applied.

The fifth transistor TR5 may be turned off in response to a high-level voltage VGH applied to the second node N2.

The sixth transistor TR6 may be turned off in response to a high-level voltage VGH applied to the third node N3.

The seventh transistor TR7 may be turned on in response to a high-level voltage VGH applied to the second node N2. A low-level voltage VGL may be applied to the first output terminal 421.

The fourth transistor TR4 may be turned on in response to a low-level voltage VGL applied to the first output terminal 421. The second output terminal 422 may be electrically connected to the fourth input terminal 414, and the i-th carry signal CR[i] may have a high-level voltage VGH.

Referring to FIG. 10, the third period PR3 is described.

In the third period PR3, the first transistor TR1 may be controlled in response to the first clock signal CLK1. The first node N1 may be electrically connected to the second input terminal 412, and a voltage of the first node N1 may be reduced from a high-level voltage VGH to a low-level voltage VGL.

The second transistor TR2 may be primarily turned on in response to a low-level voltage VGL applied to the third input terminal 413. The third node N3 may be electrically connected to the first node N1. Thereby, a low-level voltage VGL may be applied to the third node N3. The second transistor TR2 may, secondarily, be in a turn-off state where no current flows as a result of the low-level voltage VGL being applied to both ends.

The third transistor TR3 may be primarily turned on in response to a low-level voltage VGL applied to the third input terminal 413. The second node N2 may be electrically connected to the first node N1. Thereby, a low-level voltage VGL may be applied to the second node N2. The third transistor TR3 may, secondarily, be in a turn-off state where no current flows as a result of the low-level voltage VGL being applied to both ends.

The fifth transistor TR5 may be turned on in response to a low-level voltage VGL applied to the second node N2. Thereby, the i-th carry signal CR[i] may be lowered from a high-level voltage VGH to a low-level voltage VGL. By the coupling effect of the first capacitor C1, a voltage level of the second node N2 may be lowered from a low-level voltage VGL to a second level voltage LV2. By the coupling effect of the second capacitor C2, a voltage level of the third node N3 may be lowered from a low-level voltage VGL to a first level voltage LV1. Thereby, the fifth transistor TR5 may be stabilized and turned on more quickly. The second output terminal 422 may be electrically connected to the third input terminal 413. The i-th carry signal CR[i] may be stepped down from a high-level voltage VGH to a low-level voltage VGL. Thereby, the i-th carry signal CR[i] may be effectively provided to a next stage, thereby improving the overall response speed of the scan drive circuit 130 (see FIG. 1).

The sixth transistor TR6 may be turned on reliably and more quickly in response to a first level voltage LV1 applied to the third node N3. The first output terminal 421 may be electrically connected to the fifth input terminal 415. The i-th output signal OUT[i] may rise from a low-level voltage VGL to a high-level voltage VGH.

The seventh transistor TR7 may be turned off reliably and more quickly in response to a second level voltage LV2 applied to the second node N2.

The fourth transistor TR4 may be turned off in response to a high-level voltage VGH applied to the first output terminal 421. As described above, as the sixth transistor TR6 is turned on more reliably and more quickly, the fourth transistor TR4 may likewise be turned off more reliably and more quickly.

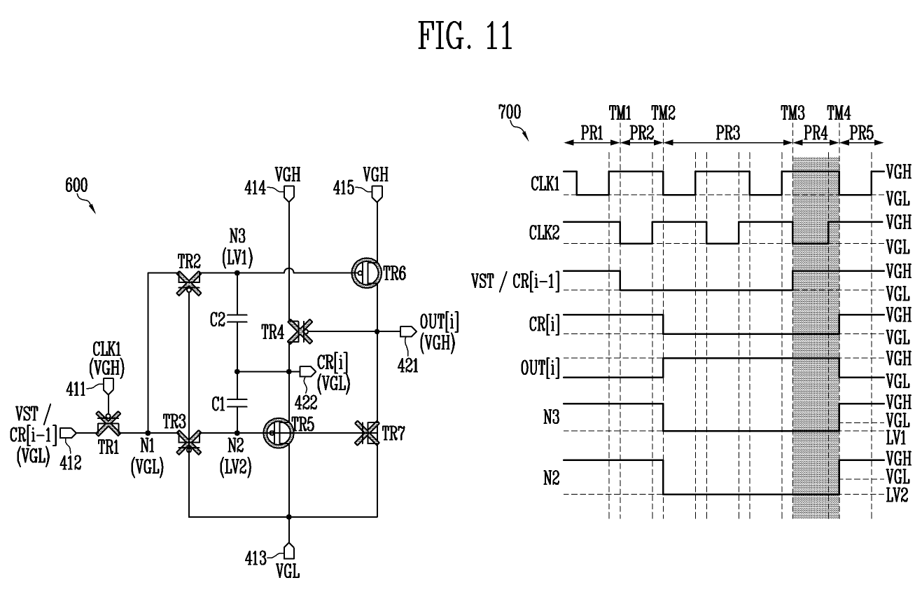

Referring to FIG. 11, the fourth period PR4 is described.

In the fourth period PR4, the first transistor TR1 may be turned off in response to the first clock signal CLK1 having a high-level voltage VGH. A low-level voltage VGL may be applied to the first node N1.

The second transistor TR2 and the third transistor TR3 may be in a turn-off state where no current flows as a low-level voltage VGL is applied across both ends.

The fifth transistor TR5 may be turned on in response to a second level voltage LV2 applied to the second node N2. The i-th carry signal CR[i] may have a low-level voltage VGL.

The sixth transistor TR6 may be turned on in response to a first level voltage LV1 applied to the third node N3. The first output terminal 421 may be electrically connected to the fifth input terminal 415. The i-th output signal OUT[i] may have a high-level voltage VGH.

The seventh transistor TR7 may be turned off in response to a second level voltage LV2 being applied to the second node N2.

The fourth transistor TR4 may be turned off in response to a high-level voltage VGH applied to the first output terminal 421.

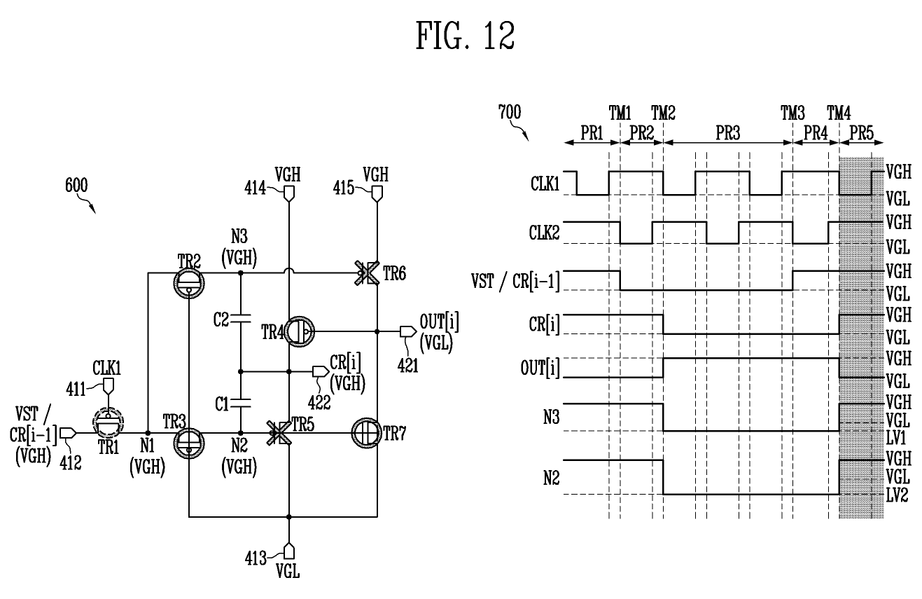

Referring to FIG. 12, the fifth period PR5 is described.

In the fifth period PR5, the first transistor TR1 may be controlled in response to the first clock signal CLK1. The first node N1 may be electrically connected to the second input terminal 412, and a high-level voltage VGH may be applied to the first node N1.

The second transistor TR2 and the third transistor TR3 may be turned on in response to a low-level voltage VGL applied to the third input terminal 413. The second node N2 and the third node N3 may be electrically connected to the first node N1 such that a high-level voltage VGH may be applied.

The fifth transistor TR5 may be turned off in response to a high-level voltage VGH applied to the second node N2.

The sixth transistor TR6 may be turned off in response to a high-level voltage VGH applied to the third node N3.

The seventh transistor TR7 may be turned on in response to a high-level voltage VGH applied to the second node N2. A low-level voltage VGL may be applied to the first output terminal 421.

The fourth transistor TR4 may be turned on in response to a low-level voltage VGL applied to the first output terminal 421. The second output terminal 422 may be electrically connected to the fourth input terminal 414, and the i-th carry signal CR[i] may have a high-level voltage VGH.

According to aspects of the present disclosure, a voltage of a level lower than a low-level voltage VGL may be applied to the gate electrode of the seventh transistor TR7 including an N-type semiconductor. Accordingly, a voltage difference (i.e., "Vgs") between a gate electrode and a source electrode of the seventh transistor TR7 may be reduced to less than 0 Volt (V). Thereby, the seventh transistor TR7 may be effectively turned off.

According to aspects of the present disclosure, capacitors (e.g., the first capacitor C1 and/or the second capacitor C2) are not continuously charged and discharged in response to the toggling of the clock signals CLK1 and CLK2. Accordingly, the power consumption of the scan drive circuit 130 (see FIG. 1) may be reduced.

Referring to FIGS. 4 to 6 described above, the stage circuits 400, 500, and 600 according to aspects of the present disclosure may include seven transistors TR1 to TR7 and two or fewer capacitors C1 and C2. Thus, a stage circuit 400, 500, or 600 with a simple structure may be realized. Thereby, the area of the non-display area NDA (see FIG. 1) or the area of a bezel within the display device 100 (see FIG. 1) may be reduced.

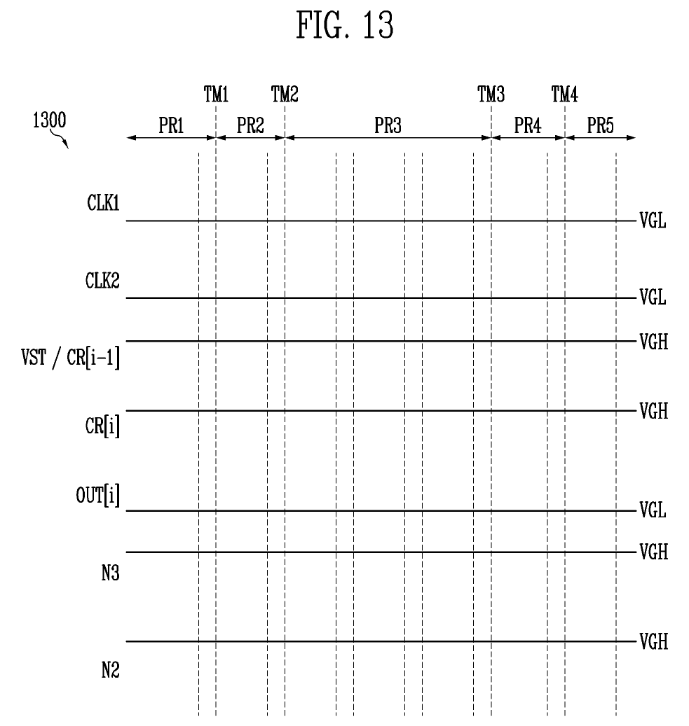

FIG. 13 is a timing diagram of a driving method 1300 according to an aspect during low frequency driving.

Referring to FIG. 13, during low frequency driving, the driving method 1300 may cause the voltages of each signal and each node to remain substantially constant during the first to fifth periods PR1 to PR5.

The low frequency driving may refer to driving that relatively lowers a refresh frame rate at which an image is displayed on the display device 100 (see FIG. 1). For example, if the display device 100 displays an image at a refresh frame rate of about 60 Hertz (Hz) during normal operation, the refresh frame rate at which the image is displayed on the display device 100 during low frequency driving may be about 30 Hz (Hz) or less, for example, the refresh frame rate may be about 1 Hz. However, aspects of the present disclosure are not limited thereto.

Referring further to FIGS. 2A and 2B, during low frequency driving, at least one of the transistors included in the pixel PXL may not operate (or may not turn on) within a drive cycle. For example, referring to FIG. 2A, the second pixel transistor PTR2 may not operate during low frequency driving, thereby preventing a data voltage Vdata from being written to the pixel circuit PXC. For example, referring to FIG. 2B, the third pixel transistor PTR3 and the fourth pixel transistor PTR4 may not operate during low frequency driving, and the data voltage Vdata pre-written in the first pixel node PN1 may not be initialized.

In low frequency driving, the first clock signal CLK1 may have a low-level voltage VGL during the first to fifth periods PR1 to PR5. The second clock signal CLK2 may have a low-level voltage VGL. The start signal VST or the (i-1)-th carry signal CR[i-1] may have a high-level voltage VGH. The i-th output signal OUT[i] may have a low-level voltage VGL. A high-level voltage VGH may be applied to the third node N3. A high-level voltage VGH may be applied to the second node N2.

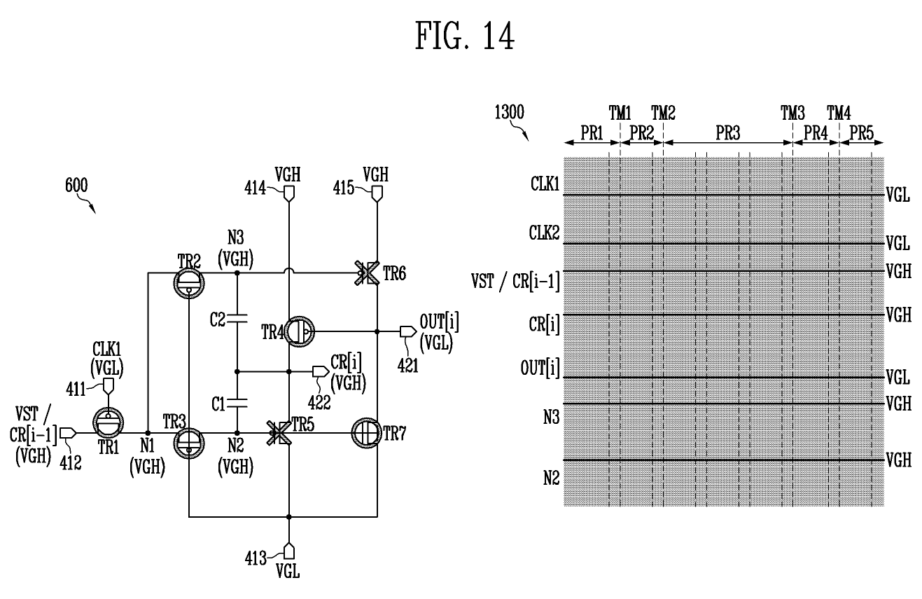

FIG. 14 is a diagram illustrating the stage circuit 600 according to the aspect of FIG. 6 in relation to the driving method 1300 of FIG. 13.

Referring to FIG. 14, first to fifth periods PR1 to PR5 of low frequency driving are described.

In low frequency driving, the first transistor TR1 may be turned on in response to the first clock signal CLK1 having a low-level voltage VGL. The first node N1 may be electrically connected to the second input terminal 412, and a high-level voltage VGH may be applied to the first node N1.

The second transistor TR2 and the third transistor TR3 may be turned on in response to a low-level voltage VGL applied to the third input terminal 413. The second node N2 and the third node N3 may be electrically connected to the first node N1 such that a high-level voltage VGH may be applied.

The fifth transistor TR5 may be turned off in response to a high-level voltage VGH applied to the second node N2.

The sixth transistor TR6 may be turned off in response to a high-level voltage VGH applied to the third node N3.

The seventh transistor TR7 may be turned on in response to a high-level voltage VGH being applied to the second node N2. A low-level voltage VGL may be applied to the first output terminal 421.

The fourth transistor TR4 may be turned on in response to a low-level voltage VGL applied to the first output terminal 421. The second output terminal 422 may be electrically connected to the fourth input terminal 414, and the i-th carry signal CR[i] may have a high-level voltage VGH.

According to aspects of the present disclosure, the clock signals CLK1 and CLK2 may be kept constant at a low-level voltage VGL during low frequency driving. Accordingly, the number of times the first capacitor C1 and/or the second capacitor C2 are charged and discharged may be reduced. Thereby, the power consumption of the scan drive circuit 130 (see FIG. 1) may be reduced.

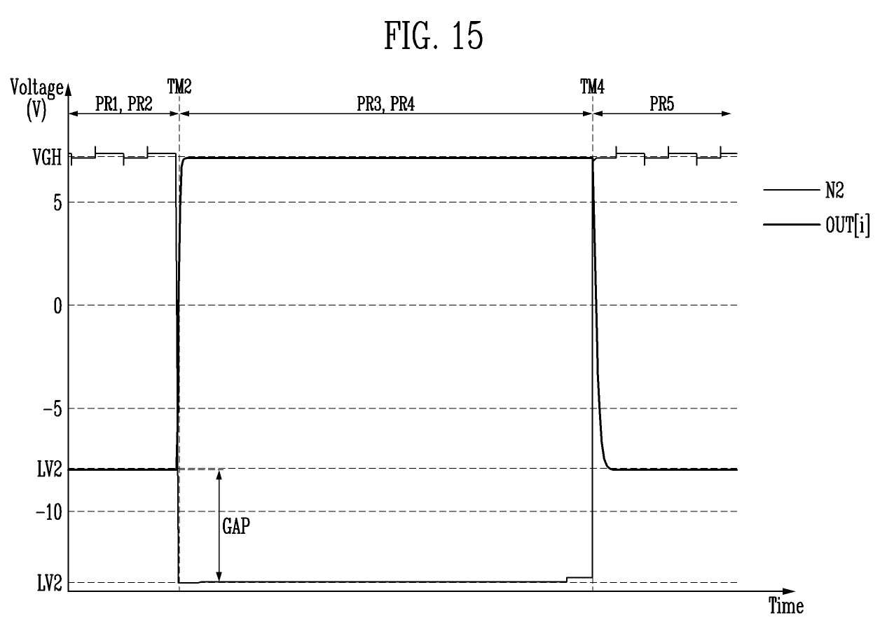

FIG. 15 is a diagram comparing a voltage level of a second node N2 with respect to a voltage level of an i-th output signal OUT[i].

Referring to FIG. 15, in the first and second periods PR1 and PR2, the i-th output signal OUT[i] may have a low-level voltage VGL. A high-level voltage VGH may be applied to the second node N2.

In the third and fourth periods PR3 and PR4, the i-th output signal OUT[i] may have a high-level voltage VGH. A second level voltage LV2 may be applied to the second node N2. The second level voltage LV2 may be lower than the low-level voltage VGL by a predetermined gap GAP. For example, the predetermined gap GAP may be about 5.5 volts. However, aspects of the present disclosure are not limited thereto.

According to aspects of the present disclosure, by controlling the voltage of the second node N2 to be lower than the low-level voltage VGL by the predetermined gap GAP, the seventh transistor TR7 (see FIGS. 4 to 6) may be effectively turned off during the third and fourth periods PR3 and PR4.

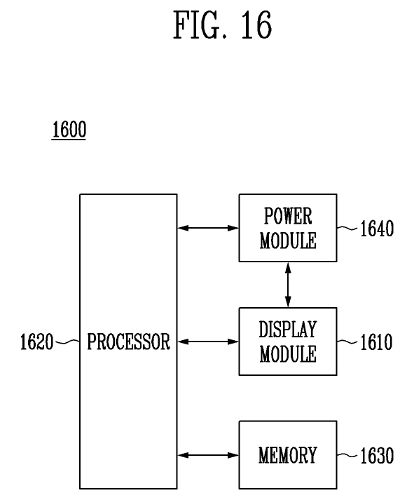

FIG. 16 is a block diagram of an electronic device 1600 according to an aspect of the present disclosure.

Referring to FIG. 16, the electronic device 1600 according to an aspect may include a display module 1610, a processor 1620, a memory 1630, and a power module 1640.

The processor 1620 may include at least one among a central processing unit (CPU), an application processor (AP), a graphics processing unit (GPU), a communication processor (CP), an image signal processor (ISP), and a controller.

The memory 1630 may store data information required for operation of the processor 1620 or the display module 1610. When the processor 1620 executes an application stored in the memory 1630, image data signals and/or input control signals are transmitted to the display module 1610, and the display module 1610 may process the received signals to output image information via a display screen.

The power module 1640 may include a power supply module, such as a power adapter or a battery unit, and a power conversion module that converts a power supplied by the power supply module to generate a power required for operation of the electronic device 1600.

At least one of each of the configurations of the electronic device 1600 described above may be included within the display device 100 (see FIG. 1) according to the aspects described above. Additionally, some of the individual modules that are functionally included within one module may be included within the display device 100 and others may be provided separately from the display device 100. For example, the display device 100 may include the display module 1610, while the processor 1620, the memory 1630, and the power module 1640 may be provided in the form of other devices within the electronic device 1600 that are not the display device.

In an aspect, the processor 1620 according to aspects of the present disclosure may include the host HST (see FIG. 1) described above.

In an aspect, the electronic device 1600 according to aspects of the present disclosure may include the electronic device ED (see FIG. 1) described above.

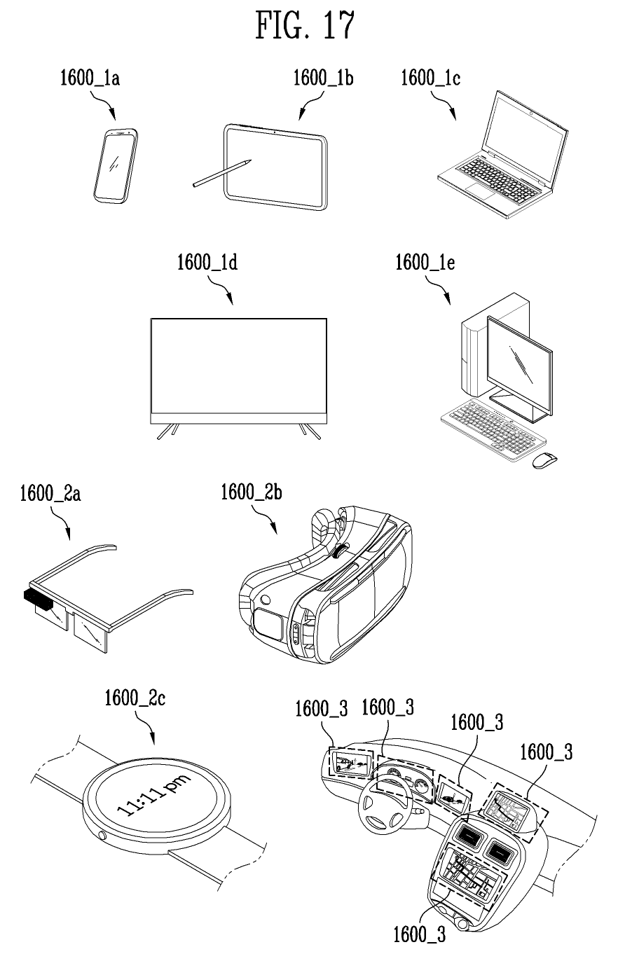

FIG. 17 is a schematic diagram of an electronic device according to various aspects.

Referring now to FIG. 17, various electronic devices with display devices according to aspects may include electronic devices for displaying images, such as a smartphone 1600_1a, a tablet PC 1600_1b, a laptop 1600_1c, a television 1600_1d, a desk monitor 1600_1e, as well as wearable electronic devices including display modules such as a smart glass 1600_2a, a head-mounted display 1600_2b, a smart watch 1600_2c, and the like, and an automotive electronic device 1600_3 including display modules such as of an instrument panel an automobile, a center fascia, a center information display (CID) disposed on a dashboard, a room mirror display, and the like.

According to aspects of the present disclosure, a stage circuit, a display device including the same, and an electronic device including the same, an output signal may be reliably controlled.

The foregoing referenced drawings and detailed description of the present disclosure are merely exemplary and are used for the purpose of illustrating the present disclosure and are not intended to limit the present disclosure. Therefore, one having ordinary knowledge in the art will understand that various modifications and other equally valid aspects are possible therefrom.

What is claimed is:

1. A stage circuit comprising:
an input part configured to connect between a second input terminal and a first node in response to a signal input to a first input terminal;
a stabilizing part configured to connect between the first node and a second node in response to a voltage input to a third input terminal; and
a first output part including a transistor that includes at least one N-type semiconductor configured to electrically connect a first output terminal and a third input terminal in response to a voltage applied to the second node, the first output part configured to electrically connect the first output terminal and a fifth input terminal.

2. The stage circuit of claim 1, wherein the input part includes a first transistor including a gate electrode connected to the first input terminal, the first transistor electrically connecting the second input terminal and the first node.

3. The stage circuit of claim 1, wherein the stabilizing part includes:
a second transistor including a gate electrode electrically connected to the third input terminal, the second transistor electrically connecting the first node and the first output part; and
a third transistor including a gate electrode electrically connected to the third input terminal, the third transistor electrically connecting the first node and the second node.

4. The stage circuit of claim 1, further comprising:
a second output part configured to electrically connect a second output terminal to the third input terminal in response to a voltage applied to the second node, and the second output part configured to electrically connect the second output terminal to a fourth input terminal in response to a voltage applied to the first output terminal.

5. The stage circuit of claim 4, wherein the second output part includes:
a fourth transistor including a gate electrode electrically connected to the first output terminal, the fourth transistor electrically connecting the fourth input terminal and the second output terminal;
a fifth transistor including a gate electrode electrically connected to the second node, the fifth transistor electrically connecting the third input terminal and the second output terminal; and
a first capacitor having one electrode electrically connected to the second node and another electrode electrically connected to the second output terminal.

6. The stage circuit of claim 5, wherein the second output part further includes:
a second capacitor having one electrode electrically connected to the second output terminal and another electrode electrically connected to a third node,
wherein the third node is connected to the stabilizing part and the first output part.

7. The stage circuit of claim 1, wherein the first output part includes:
a sixth transistor including a gate electrode electrically connected to the stabilizing part, the sixth transistor electrically connecting the fifth input terminal and the first output terminal; and
a seventh transistor including a gate electrode electrically connected to the second node and electrically connected between the third input terminal and the first output terminal,
wherein at least one of the sixth transistor and the seventh transistor includes the N-type semiconductor.

8. The stage circuit of claim 7, wherein the sixth transistor and the seventh transistor operate alternately in response to a voltage of the first node.

9. The stage circuit of claim 7, wherein the sixth transistor and the seventh transistor include different types of semiconductors.

10. The stage circuit of claim 5, wherein the first output includes a sixth transistor configured to apply a high-level voltage to the first output terminal, and
wherein the fourth transistor is configured to be turned off in response to the high-level voltage applied to the first output terminal so that a low-level voltage is applied to the second output terminal.

11. The stage circuit of claim 5, wherein the output part includes a sixth transistor configured to apply a high-level voltage to the first output terminal, and
wherein, when a turn-on level voltage is applied to the first input terminal and when a low-level voltage is applied to the first node by connecting the first node to the second input terminal, the sixth transistor is turned on to apply the high-level voltage to the first output terminal.

12. The stage circuit of claim 4, wherein an output signal output from the first output terminal and a carry signal output from the second output terminal are in inverse phase with each other.

13. The stage circuit of claim 7, wherein each of the first to sixth transistors includes a P-type semiconductor.

14. The stage circuit of claim 1, wherein the first input terminal is configured to receive a clock signal, and
wherein, in low frequency driving, the clock signal has a low-level voltage.

15. The stage circuit of claim 14, wherein the first output terminal is connected to a pixel,
wherein the pixel includes:
a first pixel transistor including a gate electrode electrically connected to a first pixel node, and connected between a second pixel node and a third pixel node;
a second pixel transistor electrically connecting between a data line and the third pixel node;
a third pixel transistor including a gate electrode electrically connected to the first output terminal, and electrically connecting between the first pixel node and the second pixel node; and
a fifth pixel transistor connected between a first power line and the third pixel node,
wherein, in the low frequency driving, the third pixel transistor is in a turn-off state.

16. The stage circuit of claim 1, wherein the second input terminal is configured to receive a start signal or a carry signal of a preceding stage circuit,
wherein the third input terminal is configured to receive a low-level voltage,
wherein a fourth input terminal and the fifth input terminal are configured to receive a high-level voltage,
wherein the first output terminal is configured to output an output signal corresponding to a scan signal, and
wherein the second output terminal is configured to output a carry signal.

17. A display device comprising:
a display panel including a plurality of pixels, a plurality of scan lines connected to the plurality of pixels, and a plurality of data lines connected to the plurality of pixels;
a scan drive circuit including a plurality of stage circuits configured to supply a scan signal to the plurality of scan lines; and
a data drive circuit configured to supply a data signal to the plurality of data lines,
wherein at least one of the plurality of stage circuits comprises:
a first transistor including a gate electrode connected to a first input terminal, and electrically connected between a second input terminal and a first node;
a second transistor including a gate electrode connected to a third input terminal, and connected to the first node;
a third transistor including a gate electrode connected to the third input terminal, and electrically connecting between the first node and a second node;
a fourth transistor including a gate electrode connected to a first output terminal, the fourth transistor electrically connecting between a fourth input terminal and a second output terminal, the first output terminal configured to output the scan signal;
a sixth transistor including a gate electrode connected to the second transistor, the sixth transistor electrically connecting between a fifth input terminal and the first output terminal; and
a seventh transistor including a gate electrode connected to the second node, the seventh transistor electrically connecting between the third input terminal and the first output terminal, and
wherein at least one of the sixth transistor and the seventh transistor includes an N-type semiconductor.

18. The display device of claim 17, wherein at least one of the plurality of pixels includes:
a first pixel transistor including a gate electrode connected to a first pixel node, and connected between a second pixel node and a third pixel node;
a second pixel transistor including a gate electrode connected to a first sub-scan line, and electrically connecting between any one of the plurality of data lines and the third pixel node; and
a third pixel transistor including a gate electrode connected to a second sub-scan line, the third pixel transistor electrically connecting the first pixel node and the second pixel node in response to the scan signal, and including the N-type semiconductor.

19. An electronic device comprising:
a processor that outputs a control signal; and
a display device including a timing controller configured to control a plurality of stage circuits to output a scan signal in response to the control signal,
wherein at least one of the plurality of stage circuits includes:
a first transistor including a gate electrode connected to a first input terminal, the first transistor configured to switch an electrical connection between a second input terminal and a first node;
a second transistor including a gate electrode connected to a third input terminal, the second transistor connected to the first node;
a third transistor including a gate electrode connected to the third input terminal, the third transistor configured to switch an electrical connection between the first node and a second node;
a fourth transistor including a gate electrode connected to a first output terminal, the fourth transistor configured to switch an electrical connection between a fourth input terminal and a second output terminal, the first output terminal being configured to output the scan signal;
a fifth transistor including a gate electrode connected to the second node, the fifth transistor configured to switch an electrical connection between the third input terminal and the second output terminal;
a sixth transistor including a gate electrode connected to the second transistor, the sixth transistor configured to switch an electrical connection between a fifth input terminal and the first output terminal;
a seventh transistor including a gate electrode connected to the second node, the seventh transistor configured to switch an electrical connection between the third input terminal and the first output terminal; and
a capacitor connected between the second node and the second output terminal,
wherein at least one of the sixth transistor and the seventh transistor includes an N-type semiconductor.

20. The electronic device of claim 19, wherein the seventh transistor includes the N-type semiconductor.
